(19) United States
(12) Patent Application Publication
(10) Pub. No.: US 2015/0135829 A1
(43) Pub. Date: May 21, 2015

(54) Levitation of Materials in Paramagnetic Ionic Liquids

(71) Applicant: Presidents and Fellows of Harvard College, Cambridge, MA (US)

(72) Inventors: George M. Whitesides, Newton, MA (US); David Bwambok, Allston, MA (US); Martin Mwangi Thuo, Watertown, MA (US); Katherine A. Mirica, Waltham, MA (US); Manza Atkinson, Somerville, MA (US)

(73) Assignee: PRESIDENTS AND FELLOWS OF HARVARD COLLEGE, Cambridge, MA (US)

(21) Appl. No.: 14/407,736

(22) PCT Filed: Jun. 14, 2013
(86) PCT No.: PCT/US13/45769

§ 371 Date: Dec. 12, 2014

Related U.S. Application Data
(60) Provisional application No. 61/659,715, filed on Jun. 14, 2012.

(51) Int. Cl. G01N 9/00; G01B 21/00; H01F 7/02; G01R 33/12

(52) U.S. Cl. CPC G01N 9/00; G01R 33/12; G01B 21/00; H01F 7/02
USPC 73/32 R

(57) ABSTRACT

This present disclosure describes the utility of paramagnetic ionic liquids for density-based measurements using magnetic levitation (MagLev), The physical properties of paramagnetic ionic liquids, including density, magnetic susceptibility, glass transition temperature, melting point, thermal decomposition temperature, viscosity, and hydrophobicity can be tuned by altering the cation or anion.

### RELATED APPLICATIONS

This application claims the benefit of the earlier filing date of U.S. Patent Application No. 61/659,715, filed on Jun. 14, 2012, the contents of which are incorporated by reference herein in its entirety.

This application may be related to the following patent applications:

U.S. Patent Application No. 60/947,214, filed on Jun. 29, 2007; U.S. Patent Application No. 60/952,483, filed on Jul. 27, 2007; PCT Patent Application No. US 2008/68797, filed on Jun. 30, 2008; U.S. patent application Ser. No. 12/666,132, filed on Jul. 8, 2010, now published as U.S. Patent Publication No. 2010/0285606; U.S. Patent Application No. 61/425,023, filed on Dec. 20, 2010; PCT Patent Application No. US 2011/66169, filed on Dec. 20, 2011; U.S. Patent Application No. 61/417,774, filed on Nov. 29, 2010; PCT Patent Application No. US 2011/62399, filed on Nov. 29, 2011; and U.S. Patent Application No. 61/527,322, filed on Aug. 25, 2011.

### GOVERNMENT SUPPORT

This work was supported by the United States government under the National Institute of Health postdoctoral Grant #5F32AI089698-03. The government has certain rights in this invention.

### BACKGROUND

Recently, a platform that is capable of determining the density of an object, and monitoring changes in density of an object(s), based on magnetic levitation (Maglev) was developed. MagLev has the potential to be broadly useful, in particular for: (i) the analysis of food and water, (ii) measurements of protein-ligand binding, (iii) forensics, (iv) self-assembly, and (v) density-based separations. This method relies on the use of paramagnetic solutions that are typically generated by dissolving a paramagnetic salt in a solvent, such as water, aqueous solutions, polar liquids (e.g., alcohols, acids) or non-polar liquids (e.g., alkanes, benzene/aromatics).

### SUMMARY

The levitation of diamagnetic materials in a paramagnetic ionic liquid is described. Methods to levitate diamagnetic materials with a much broader range of different densities, as compared to the densities that are currently available with an aqueous solution into which paramagnetic salts have been dissolved, are also provided.

In other aspects, techniques for manipulating, assembling, sorting, detecting, diagnosing, analyzing and/or measuring diamagnetic materials suspended in a MagLev device are described. Systems and methods described herein extend the range of materials and shelf life for manipulating, sorting, analyzing and/or measuring diamagnetic materials. The protocols for the determination of an object's density and/or the separation of at least two diamagnetic objects based on their densities require only a paramagnetic ionic liquid, two magnets, and (optionally) a simple diagnostic device (e.g., a ruler or other scale or an imaging device). Separation may also be based, in principle, on the combination of magnetic forces with forces other than gravity.

Diamagnetic objects of different densities levitate to different heights when placed in a paramagnetic liquid within the MagLev device: the levitation height of the object is reached when the magnetic force (supplied by the magnets within the MagLev device) acting on the diamagnetic object is equal to the opposing, gravitational, force. The paramagnetic liquid used herein provides improved properties. For example, it provides reduced susceptibility to changes in concentration and thus density over time (as compared to paramagnetic solutions where the solvent can evaporate over time). Paramagnetic ionic liquids provide a non-aqueous medium that permits magnetic levitation of water soluble materials. Lastly, a broader range of densities can be investigated than is possible with paramagnetic solutions involving a paramagnetic salt and a solvent.

In certain embodiments, a method for levitating a diamagnetic material is described. The method can include providing a levitating medium comprising a paramagnetic ionic liquid; providing a diamagnetic material in the levitating medium; applying a magnetic field to the levitating medium and the material; and determining the levitation height of the material.

In certain embodiments, the levitating medium has a vapor pressure that is about zero at room temperature.

In certain embodiments, the density of the levitating medium is in the range of 0.65-2.3 g mL⁻¹.

In certain embodiments, the levitating medium is free of non-ionic liquid solvent.

In certain embodiments, the levitating medium further comprises a diamagnetic ionic liquid.

In certain embodiments, the levitation height is correlated to density.

In certain embodiments, the levitating medium is a liquid below 0° C.

In certain embodiments, the levitating medium is a liquid above 100° C.

In certain embodiments, a method of measuring the density of a liquid or a solid is described. In certain embodiments, the method can include providing a levitating medium comprising a paramagnetic ionic liquid: introducing a solid or a solvent-immiscible liquid into the levitating medium; applying a magnetic field having a magnetic gradient to the levitating medium and allowing the solid or liquid to levitate at a position in the levitating medium relative to the magnetic field; and correlating the levitation height with density.

In certain embodiments, the levitating medium is a liquid below 0° C.

In certain embodiments, the levitating medium is a liquid above 100° C.

In certain embodiments, the levitating medium has a vapor pressure that is about zero at room temperature.

In certain embodiments, the density of the levitating medium is in the range of 0.65-2.3 g mL⁻¹.

In certain embodiments, the levitating medium is free of non-ionic liquid solvent.

In certain embodiments, the levitating medium further comprises a diamagnetic ionic liquid.

In certain embodiments, correlating the levitation height with density comprises comparing the levitation height of the unknown solid or solvent-immiscible liquid with a calibration curve to determine the density of the unknown solid or solvent-immiscible liquid.

In certain embodiments, the diamagnetic object is a drug and the density determination can distinguish between a known drug product and a counterfeit drug product.

### BRIEF DESCRIPTION OF THE DRAWINGS

FIG. 1 is a schematic representation (A) of the magnetic field, (B) the distribution of magnetic forces, and (C) a graph of the calculated magnitude of magnetic field along the axis of the magnets used for separation.

FIG. 2 is a schematic illustration of a device for determining the location of a diamagnetic object in paramagnetic liquid exposed to a magnetic force.

FIG. 3 shows differential scanning calorimetry (DSC) curves of two different paramagnetic ionic liquids obtained by cooling the sample from 20° C. to −75° C. at 10° C./minute, followed by heating the sample to room temperature at the same rate.

FIG. 4 shows a thermogravimetric analysis (TGA) thermogram of [BMIM]₃[DyCl₆] paramagnetic ionic liquid. The change in weight as a function of temperature was monitored by heating the sample from room temperature to 700° C. at a ramp rate of 10° C./min.

FIG. 5 shows a schematic illustration for measuring the densities of diamagnetic objects using paramagnetic ionic liquids in Maglev.

FIG. 6A-6C shows photographs demonstrating the levitation of glass and polyethylene density standard beads in different paramagnetic ionic liquids.

FIG. 7A-7B is a graph showing the relationship between the levitation height and the density of beads having known densities that are levitated in imidazolium-based paramagnetic ionic liquids.

FIG. 8 is a graph showing the relationship between the levitation height and the density of beads having known densities that are levitated in amino acid ester-(L-alanine methyl ester)-based paramagnetic ionic liquids.

FIG. 9 is a graph showing the relationship between the levitation height and the density of beads having known densities that are levitated in ALIQUAT-based paramagnetic ionic liquids; this also shows the different range of densities accessible to MagLev by varying the (A) anion or (B) the halide.

FIG. 10 demonstrates density-based differentiation of brand name and generic pills using paramagnetic ionic liquids with Maglev. (A) Aspirin (i) St. Joseph (ρ=1.20 g/mL), (ii) CVS (ρ=1.29 g/mL) using [AlaCl]₃[DyCl₆](diluted with [DMIM][SO₄], 1:1 v/v) (B) Naproxen (i) Bayer (ii) CVS using [BMIM][FeCl₄] (diluted 1.5-times with [DMIM][SO₄]). The paramagnetic ionic liquid, [BMIM][FeCl₄](diluted 1.5× using [DMIM][SO₄]), was used to levitate the pills.

FIG. 11 demonstrates density measurements at room temperature and at −20° C. using paramagnetic ionic liquids and an aqueous solution of 1M MnCl₂. The paramagnetic ionic liquid, [Aliq]₃[HoCl₆], can be used for density measurements using MagLev at sub-zero temperatures, while aqueous 1M MnCl₂ is frozen at −20° C.

FIG. 12 shows the dynamic separation of delrin beads (d=1.43 g/mL) with different sizes ( 5/32″ and ⅛″ diameters) during magnetic levitation in [AlaCl][HoCl₆] within 60 seconds.

### DETAILED DESCRIPTION

The principle of magnetic levitation described herein involves subjecting diamagnetic materials suspended in a paramagnetic liquid to a magnetic field, such as a magnetic field gradient that forms between two magnets. The magnetic field generates a non-uniform pressure equivalent to the magnetic energy density in the paramagnetic liquid. In a magnetic field gradient, diamagnetic objects appear to be repelled from the regions of high magnetic field; in actuality, the diamagnetic object is displaced by an equal volume of the paramagnetic liquid. The attractive interaction between the paramagnetic liquid and the regions of high magnetic field, can result in the “levitation” of the diamagnetic object. The “levitation height” of an object, in the two magnet setup, can be defined as desired. For example, in certain embodiments, “levitation height” can be defined as the distance between the center of the levitating object and the top surface of the bottom magnet, but any desired reference point can be utilized. By applying the magnetic field in such a manner that the force on the objects is opposed by another uniform force (e.g., the force of gravity), a balance is achieved for the diamagnetic object that is directly related to its density. This phenomenon can be used to determine the density, and other properties based on their characteristic location, in a magnetic fluid.

In one aspect, the density of an object is determined with a magnetic levitation system that employs a paramagnetic ionic liquid as the paramagnetic liquid. An ionic liquid is a salt that is in a liquid state at or below 100° C. (i.e., at temperatures of less than 100° C. or between a temperature of 0° C. and 100° C.). A paramagnetic ionic liquid includes one or more ions that is paramagnetic. This paramagnetic liquid is a liquid salt and not a salt solution (e.g., a paramagnetic salt solute dissolved in an aqueous or organic solvent). As such, the paramagnetic liquid does not include a solvent and the density of the fluid is a function of the ionic liquid and not the solvent in which it is dissolved. Paramagnetic ionic liquids typically have a density in the range of 0.65-3 g/mL (e.g., 0.65-2.3 g/mL), which is higher than many salt solutions. In addition, because volatile solvents are not used, evaporation of the liquid is reduced or prevented.

Paramagnetic ionic liquids are utilized as a media for making density measurements using MagLev. The low melting points and high thermal stability of many paramagnetic ionic liquids provide large liquidus windows. The determination of the density of a diamagnetic material in temperatures below 0° C. or above 100° C. are contemplated; such a temperature range is not possible with aqueous or organic solutions, due to limitations from their freezing and/or boiling points. The use of viscous paramagnetic ionic liquids for the dynamic separation of objects of (i) different sizes but the same density or (ii) different sizes and different densities is also demonstrated.

As described in greater detail herein, compounds that exhibit very subtle differences in density occupy a unique levitation height when placed in the magnetic field of the MagLev device. This difference may be used to separate materials of different densities, to determine the purity of a specific material or analyte, to monitor solid supported chemical reactions and to determine the density of solids, liquids and solutions or other mixtures. For example, certain water soluble brand name and generic drugs can be distinguished from one another. In one or more embodiments, objects with differences in density of no more than 0.05 g/cm³, or even densities with accuracies of ±0.0002 g/cm³ are detected or distinguished. Higher resolution is expected with optimization of the methods and systems according to one or more embodiments. In one or more embodiments, differences in density are used to detect and/or distinguish between objects with and without surface modification, among molecules having different functional groups, or between complexed and uncomplexed conjugates. Changes in the levitation height of diamagnetic objects also are used to indicate a binding event and the presence of an analyte, or to monitor the progress of a chemical reaction.

### Principles of Material Characterization by Magnetic Levitation

Density-based separations of diamagnetic materials are determined by the balance between the magnetic force and the gravitational force on a diamagnetic object in a paramagnetic liquid. In a static system, the force per unit volume ( F̅/V) on an object in a magnetic field is the sum of the gravitational and magnetic forces (Equation 1),

$$\vec{F} / V = - ( {ρ}_{l} - {ρ}_{p} ) \vec{g} - \frac{( {χ}_{l} - {χ}_{p} )}{{μ}_{0}} ( \vec{B} \cdot \vec{∇} ) \vec{B} \qquad ( 1 )$$

where the density of the liquid is ρₗ, the density of the object is ρₚ, the acceleration due to gravity is g, the magnetic susceptibilities of the liquid and the object are χₗ and χₚ, respectively, the magnetic permeability of free space is μ₀, and the local magnetic field is B̅=(Bₓ, B_{y}, B_{z}).

Both the magnetic field and its gradient contribute to the magnetic force and are optimized, according to the dimensions of the system. Equation 1 can be simplified for the levitation of a point object—i.e., an infinitesimally small object—in a system at equilibrium in which the magnetic field only has a vertical component (B_{z}); that is, the two other normal components of the applied magnetic field (Bₓ, and B_{y}) are zero (Equation 2).

$$( {ρ}_{l} - {ρ}_{p} ) = \frac{( {χ}_{l} - {χ}_{p} )}{{μ}_{0}} {B}_{z} \frac{\partial {B}_{z}}{\partial z} \qquad ( 2 )$$

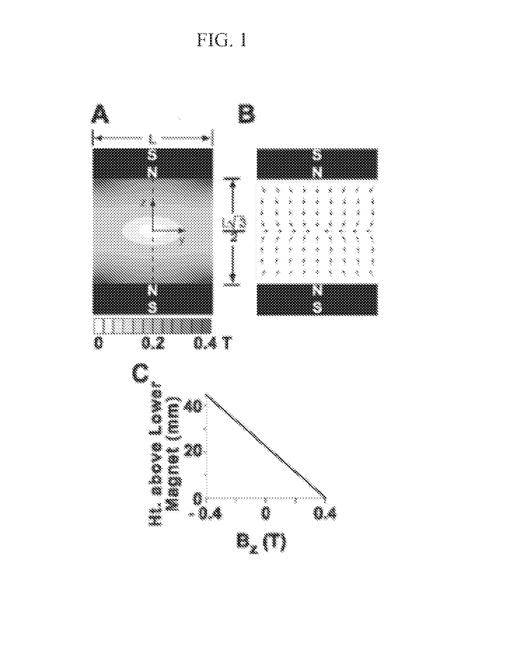

The magnetic field gradient is determined by the size, geometry, orientation, and nature or type of the magnets as illustrated in FIG. 1A. The calculated value of the magnitude of the magnetic field, | B̅|, of the system is shown for a set of magnets, 50-mm long (L), separated by a distance defined by \sqrt{3}(L/2)≈ of approximately 43 mm. The shading in the plot indicates the magnitude of the magnetic field; the darker regions correspond to higher field intensities (white ˜0 T and black is ˜0.4 T). This field was calculated using a finite element modeling software under axisymmetric boundary conditions. In one or more embodiments, a set of solid-state NdFeB magnets may be employed. In specific embodiments, NdFeB magnets with length, width, and height of 5 cm, 5 cm, and 2.5 cm, respectively, having a magnetic field of ˜0.4 T at their surface, were used to generate the required magnetic field and magnetic field gradient. Two magnets oriented towards each other in an anti-Helmholtz configuration established the magnetic field distribution in this system. In this geometry, the Bₓ and B_{y} components of the magnetic field are exactly zero. Only along the Bz axis of the magnets, the vertical dashed line in FIG. 1A, is there a magnetic field gradient. FIG. 1B illustrates the distribution of the magnetic forces on the diamagnetic material within a paramagnetic liquid. The calculation shows that a diamagnetic object would be repelled from the surfaces of the magnets and would be trapped along the axis between the magnets. The B_{z} component of the magnetic field also becomes zero over this axis, but only at the midpoint between the two magnets. The effect of the magnetic force in this geometry is to attract the paramagnetic liquid towards one or the other of the two magnets and, as a consequence, to trap all diamagnetic objects at the central region between the magnets (FIG. 1B)—i.e., where B is close to zero.

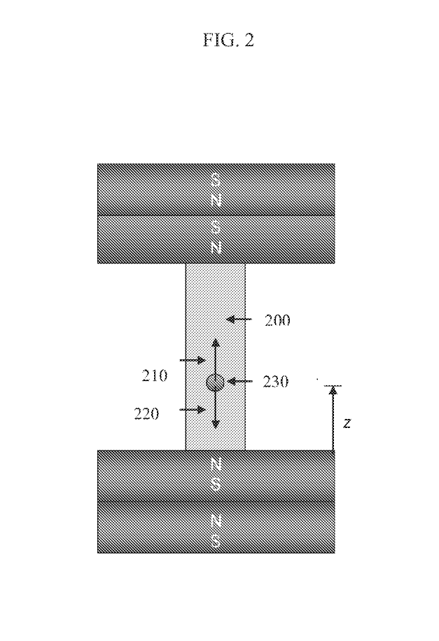

For this particular configuration, when the distance between the two magnets is approximately \sqrt{3} times the length of the magnets, the magnetic field profile is approximately linear, and the gradient of the magnetic field is approximately constant in the z-direction (FIG. 1C). FIG. 1C is a graph of the calculated magnitude of the magnetic field in the vertical direction, B_{z}, along the axis between the two magnets (the dotted line in FIG. 1A); the direction of a positive z-vector was chosen to be toward the upper magnet. The other components of the magnetic field along the chosen path are zero. Note that the gradient of the magnetic field in the vertical direction is constant—i.e., a constant slope in the variation of the magnetic field along the axis. Thus, objects of different densities will align themselves along the z-axis in predictable spacings. An exemplary system is illustrated in FIG. 2. A magnetic fluid 200 is disposed between two magnets. Magnetic force and gravity are indicated by arrows 210, 220 illustrating the opposing direction of these two forces. A diamagnetic object 230 will reach an equilibrium position within the magnetic field. In one or more embodiments, this configuration is used for separating many materials that differ in density.

### Paramagnetic Ionic Liquids

In one or more embodiments, the liquid used in MagLev methods is a paramagnetic ionic liquid. The paramagnetic ionic liquid has a positive magnetic susceptibility. The paramagnetic ionic liquid should not dissolve the materials to be levitated and/or separated by their different densities. The density of the paramagnetic ionic liquid will play a role in the materials that can be levitated and/or separated. For example, by selecting a paramagnetic ionic liquid that is more or less dense than the objects to be separated, the objects will either sink or float prior to exposure to the magnetic field gradient. The density of the paramagnetic ionic liquid may be selected such that all the objects float or sink prior to the separation process. In one or more embodiments, the density of the paramagnetic ionic liquid is in the range of 0.65-3.0 g/mL or 0.65-2.3 g/mL.

Non-limiting examples of components that can be used to form paramagnetic ionic liquids suitable for use in one or more embodiments include MnX₂, DyX₃, GdX₃, and HoX₃ (where X=Cl⁻, Br⁻, or I⁻); 1-butyl-3-methylimidazolium (BMIM) chloride, bromide, or iodide; alkyl ammonium salts such as methyl(trioctyl)ammonium chloride; alkyl phosphonium salts such as trihexyl(tetradecyl)phosphonium chloride; and amino acid esters such as glycine ethyl ester chloride. Other ionic liquids that include metal ions that impart paramagnetic properties are also contemplated.

Paramagnetic ionic liquids can be synthesized through a direct combination of various organic halides and paramagnetic metal halides. The anions of the paramagnetic ionic liquids can be synthesized from iron (III), gadolinium (III), manganese (II), holmium (III), and dysprosium (III) halide salts. The cation of the paramagnetic ionic liquids can be synthesized based on imidazolium, amino acid esters, tetra-alkylammonium and tetra-alkyl phosphonium halides, for example.

For example, paramagnetic ionic liquids can be synthesized by combining imidazolium, amino acid ester, ammonium or phosphonium halides with paramagnetic metal halides as illustrated with paramagnetic ionic liquids based on iron (III) chloride (Scheme 1). These reactions can be performed in the absence of solvent or in the presence of methanol; the methanol solvent is removed, in vacuo, prior to use. For example, Scheme 1 shows the synthesis of paramagnetic ionic liquids containing (A) imidazolium, (B) methyltrioctyl, (C) trihexyl(tetradecyl)ammonium, and (D) amino acid ester (e.g. glycine ester) type cations. Various paramagnetic ionic liquids were obtained by substituting iron (III) chloride with chlorides of Mn (II), Gd (III), Dy (III), Ho (III) and also changing the halide by replacing Cl with Br or I. [BMIM][Cl represents 1-butyl-3-methyl imidazolium chloride; [Aliq][Cl] represents methyltrioctylammonium chloride; [PR₄][Cl] represents trihexyl(tetradecyl)ammonium chloride; and [GlyC2][Cl] represents glycine ethyl ester chloride.

In one or more embodiments, the paramagnetic ionic liquid is mixed with other ionic liquid(s), such as a diamagnetic ionic liquid. For example, some suitable diamagnetic ionic liquids include 1-ethyl-3-methylimidazolium dicyanamide, trihexyltetradecylphosphonium dicyanamide, tetradecyltrihexylphosphonium bis(trifluoromethylsulfonyl)amide, 1,3-dimethylimidazolium methyl sulfate, 1-butyl-3-methylimidazolium hexafluorophosphate, 1-butyl-3-methylimidazolium trifluoromethanesulfonate, 1-butyl-3-methylimidazolium bis(trifluoromethylsulfonyl)amide, 1-butyl-3-methylimidazolium bis(perfluoroethylsulfonyl)imide, 1-butyl-3-methylimidazolium tetrafluoroborate 1,3-dimethylimidazolium methyl phosphate, 1-ethyl-3-methylimidazolium thiocyanate. The mixture of paramagnetic ionic liquid and other ionic liquids can be varied from the ratio 1:9 to 9:1 respectively, that the mixture do not get phase separated from each other.

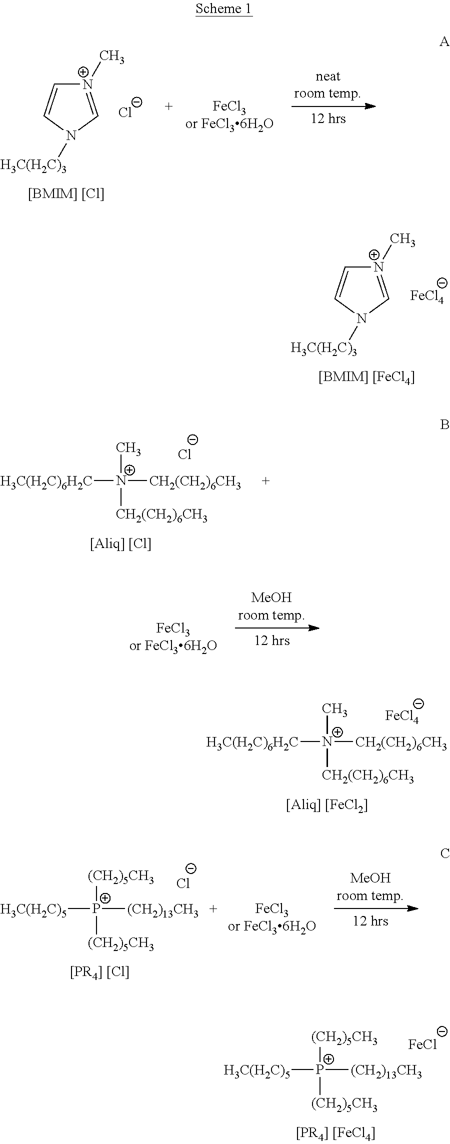

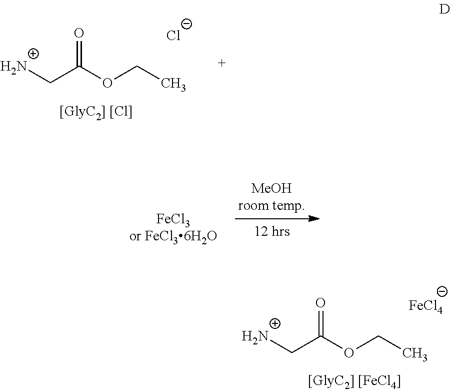

### Advantages of Paramagnetic Ionic Liquids

The present disclosure provides the following improvements over conventional MagLev systems, in which the paramagnetic medium is a solution composed of a paramagnetic salt dissolved in an aqueous or organic solvent.

First, paramagnetic ionic liquids do not suffer from evaporation of solvent. Conventional paramagnetic solutions include water, or organic-based solvents with boiling points less than water (e.g., methanol or ethanol), that can evaporate from a solution containing a non-volatile paramagnetic salt. This loss of solvent alters the concentration of the paramagnetic species, with time, and thus alters the magnetic susceptibility and the density of the solution. Such evaporation in conventional systems hinders the prolonged use and storage of paramagnetic liquid media based on water or other volatile solvents without calibration.

Second, the paramagnetic ionic liquids can provide wider range of densities that can be measured. In conventional systems, paramagnetic salts (e.g. MnCl₂) have limited solubility in water and even more limited solubility in organic solvents. This range of solubility narrows the range of densities that can be measured using these conventional paramagnetic solutions; the density of paramagnetic solutions composed of water and MnCl₂ is ˜1-1.8 g mL⁻¹ (see, e.g., Mirica et al 2009 JACS, which is incorporated herein by reference). There are a number of chelated versions of Mn⁺² and Gd⁺³ salts which are more compatible with organic solvents, however these chelated ions are much more costly than their chloride salt analogs and, in some cases, require the chelate to be synthesized.

Third, these ionic liquids are inherently paramagnetic, they can be used without dilution by solvents; paramagnetic ionic liquids thus eliminate errors or uncertainties due to variations in concentration of a paramagnetic solute. However, paramagnetic ionic liquids can be combined with other ionic liquids so that the magnetic susceptibility, viscosity and other properties of the levitating liquid can be manipulated.

Fourth, the density and magnetic susceptibility of paramagnetic ionic liquids are defined by their chemical components, and by the stoichiometry of those components. Since the stoichiometry is fixed, and since the paramagnetic ionic liquids can be used in their pure form, the magnetic susceptibility and density of each system is invariable. As a result, paramagnetic ionic liquids can be recycled easily: recycling enables the long term use of paramagnetic ionic liquids without compromising the ability of the user to make accurate measurements of density using MagLev.

Fifth, the chemical and physical properties of paramagnetic ionic liquids are defined by the ions which constitute them. These properties can easily be tuned by changing the ion; this flexibility allows ionic liquids to be produced that are either hydrophilic or hydrophobic.

Sixth, certain contaminants that may be absorbed into the ionic liquid, during analysis, may be removed by simply washing the ILs with water or organic solvent.

Seventh, paramagnetic ILs have several properties that suggest they can be useful for applications requiring prolonged use in remote regions and in hot and cold environments. They have very low vapor pressure and high thermostability. They are also generally non-toxic, non-flammable, and recyclable. Their physical properties, including density and viscosity, can be modified through changes in cation or anion. (See Welton, T. Chem Rev. 1999, 99, 2071-2083.)

Eighth, paramagnetic ionic liquids are made by simply mixing two components. As a result, they have densities and magnetic susceptibilities that are defined exactly by the stoichiometry and chemical identity of the two ionic components.

Ninth, the use of paramagnetic ionic liquids broaden the scope of measurements of density that can be made.

### Example 1

### Synthesis of Paramagnetic Ionic Liquids

Paramagnetic ionic liquids were synthesized by combining imidazolium, amino acid ester, ammonium or phosphonium halides with paramagnetic metal halides as illustrated with paramagnetic ionic liquids based on iron (III) chloride (See Scheme 1 above).

The salts 1-butyl-3-methyl imidazolium chloride (BMIM Cl), 1-butyl-3-methyl imidazolium bromide (BMIM Br), iron (III) chloride, manganese (III) chloride, gadolinium (III) chloride, gadolinium (III) bromide, holmium (III) chloride, holmium (III) bromide, dysprosium (III) chloride, trihexyl(tetradecyl)phosphonium chloride, trioctylmethylammonium chloride chloride (Aliquat® Cl), 1-butyl-3-methyl-imidazolium methyl sulfate (DMIM SO₄), L-alanine methyl ester chloride, were obtained from Sigma and used as received. Gadolinium (III) triflate (Gd OTf) was obtained from Alfa Aesar and used as received. Delrin beads were obtained from McMaster-Carr. Glass and polymeric beads with known densities were obtained from American density standards.

Except for [BMIM][FeCl₄], [GlyC₂][FeCl₂][BMIM]₂[MnCl₄], all paramagnetic ionic liquids were synthesized by mixing appropriate equivalents of the halide starting materials in methanol and allowed to stir overnight. The solvent was removed in vacuo affording paramagnetic ionic liquids in nearly quantitative yield. The synthesis of [BMIM][FeCl₄], [GlyC₂][FeCl₄] was carried out by following reported literature procedure (Satoshi Hayashi and Hiro-o Hamaguchi Chemistry Letters 2004, 33 (12) 1590-1591; Masanari Okuno and Hiro-o Hamaguchi Applied Physics Letters 2006, 89, 132506). Specifically, BMIM Cl and FeCl₃ were mixed together in a 1:1 molar ratio and stirred under nitrogen atmosphere. After stirring for 10 minutes at room temperature, BMIM FeCl₄ was obtained as a brown colored ionic liquid. This procedure was also used for BMIM MnCl₄ except that the mixture was gently heated at 60° C. for 5 minutes. The synthesized paramagnetic ionic liquids were characterized using elemental analysis (Robertson Microlit Labs, NJ). The glass transition temperature (T_{g}), melting point (Tₘ), and decomposition temperatures (T_{dec}) of the synthesized paramagnetic ionic liquids were obtained respectively using dynamic scanning calorimetry (DSC), and thermal gravimetric analysis (TGA).

The synthesized paramagnetic ionic liquids was characterized using elemental analysis. The calculated elemental compositions are in good agreement with the experimental results.

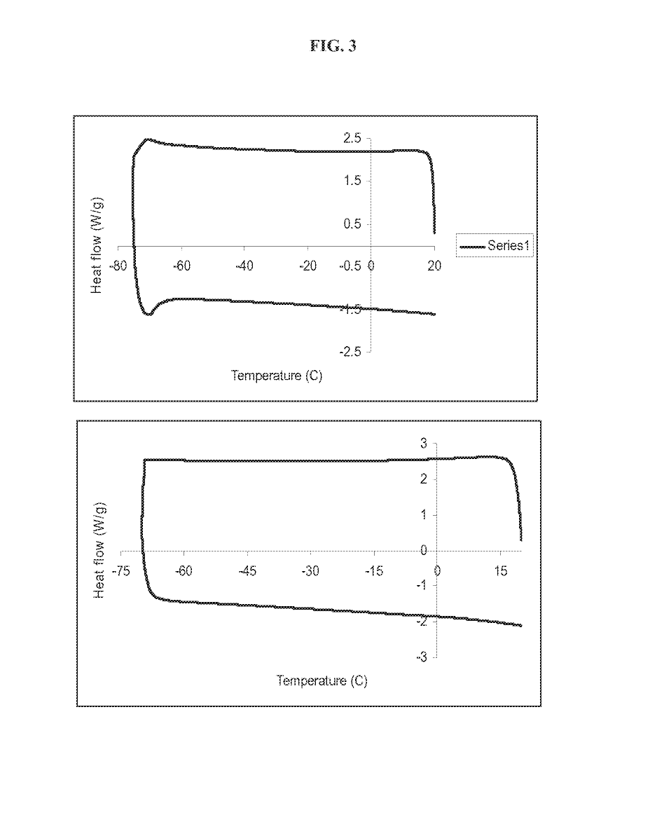

The glass transition temperatures and melting points of the synthesized paramagnetic ionic liquids were determined using differential scanning calorimetry (DSC) (see FIG. 3). Generally, most paramagnetic ionic liquids are liquid at room temperature, and some are liquid even at −75° C. For example, the glass transition temperature for [PR₄]₃[GdBr₆] is at −69° C. with no observable melting transition (see FIG. 3A), whereas [BMIM]₃[DyCl₆] shows neither glass transition nor melting point above −75° C. (see FIG. 3B).

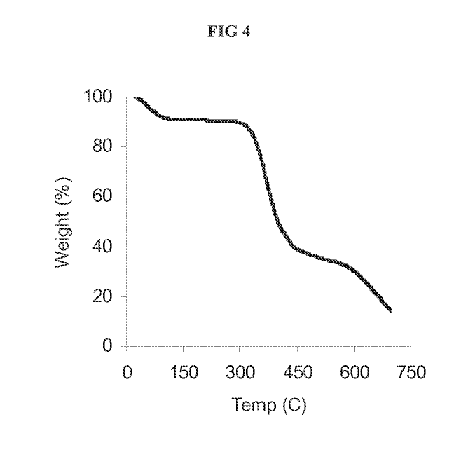

The thermal stability of the paramagnetic ionic liquids was measured using thermal gravimetric analysis (TGA). Most paramagnetic ionic liquids were thermally stable to at least 300° C. (see FIG. 4). The melting points (Tₘ), glass transition (T_{g}) and decomposition temperatures (T_{dec}) of the synthesized paramagnetic ionic liquids is provided below.

[Aliq]₃[GdCl₆]

Calculated for C₇₅H₁₆₂Cl₆GdN₃: C=61.03%, H=11.06%, N=2.85%.

Found: C=61.91%, H=12.38%, N=2.44%.

[Aliq]₃[HoBr₆]

Calculated for C₇₅H₁₆₂Br₆HoN₃: C=51.46%, H=9.33%, N=2.40%.

Found: C=50.11%, H=10.05%, N=2.14%.

Tₘ and T_{g} were not observed; T_{dec}=250° C.

[BMIM]₃[DyCl₆]

Calculated for C₂₄H₄₅DyCl₆N₆: C=36.36, H=5.72, N=10.60.

C=35.43%, H=7.32%, N=8.40%.

Tₘ and T_{g} were not observed; T_{dec}=350° C.

[BMIM]₃[DyI₆]

Calculated C₂₄H₄₅DyI₆N₆: C=21.49, H=3.38, N=6.26.

Found: C=23.61% H=4.78% N=5.24%.

[BMIM][FeCl₄]

Calculated: C=28.50% H=4.45% N=8.31%.

Found: C=30.60%, H=4.95%, N=9.04%.

[BMIM]₃[HoBr₆]

Calculated C₂₄H₄₅Br₆HoN₆: C=27.14% H=4.27% N=7.91%.

Found: C=29.69%, H=6.67%, N=6.87%.

[BMIM]₂[MnCl₄]: Tₘ=22° C., T_{g}=−40° C., T_{dec}=300° C.

[PR₄][FeCl₄]: Tₘ was not observed: T_{g}=−71° C.

[PR₄]₂[MnCl₄]: Tₘ was not observed, T_{g}=−69° C.

[PR₄]₃[GdBr₆]: Tₘ was not observed, T_{g}=−67° C.

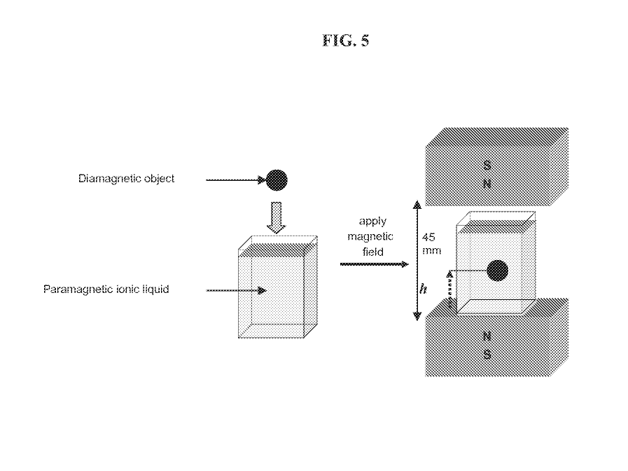

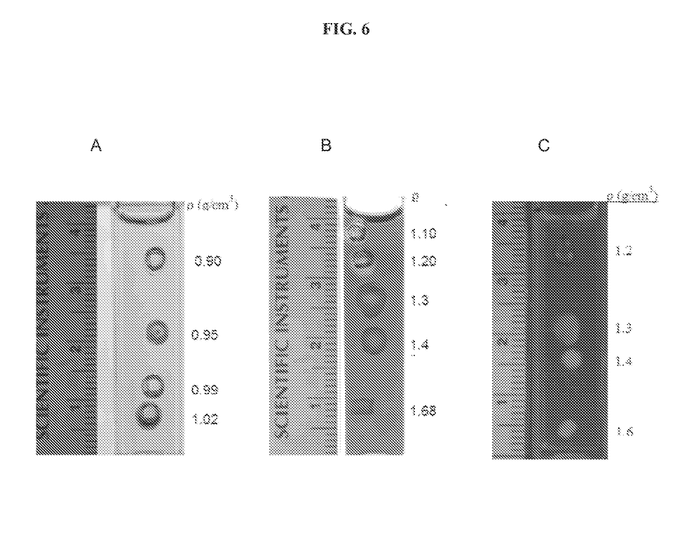

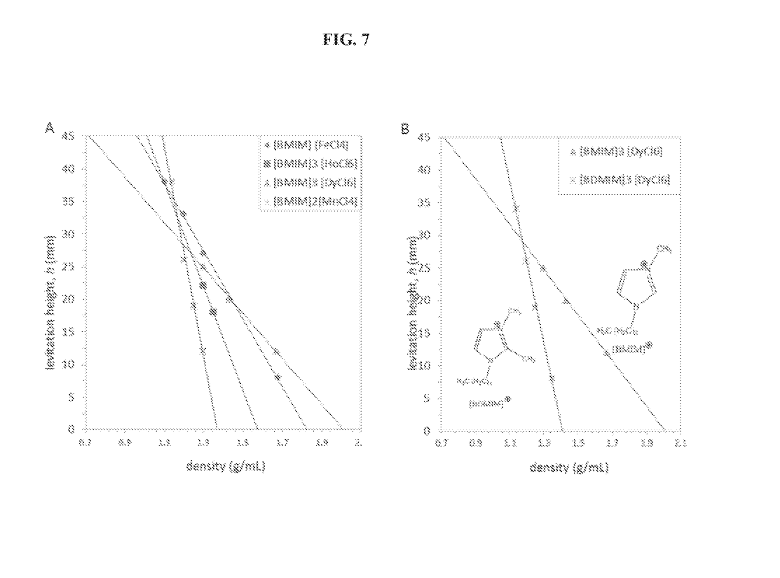

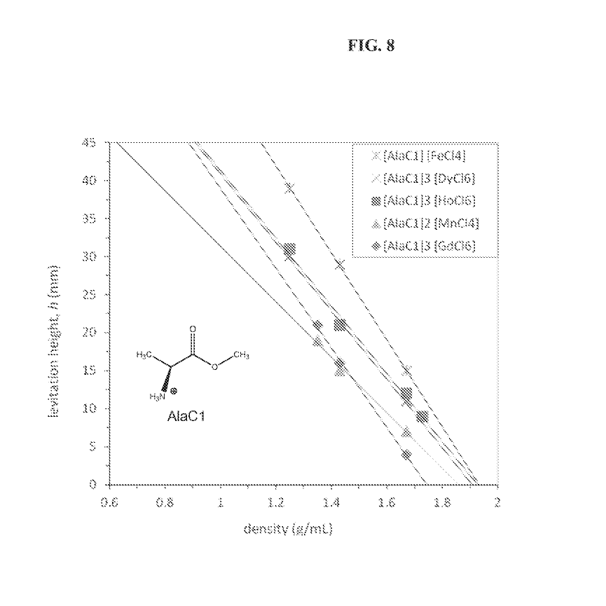

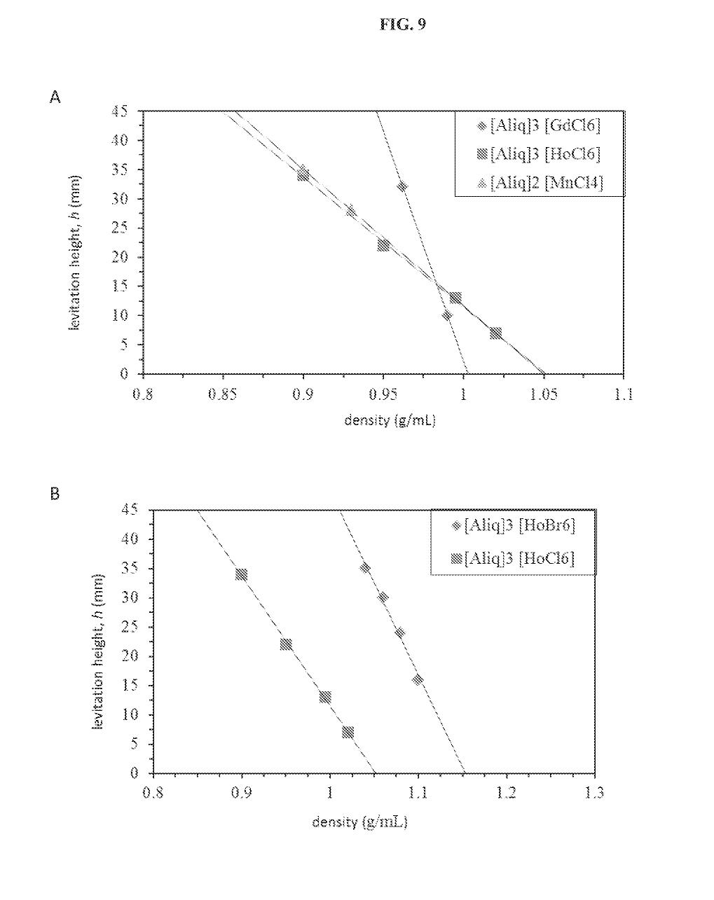

The density of a diamagnetic object was determined, from its levitation height, by suspending the object in a container filled with paramagnetic ionic liquid and placed the container between two NdFeB magnets oriented with like poles facing each other (see FIG. 5). Before using the paramagnetic ionic liquids as liquids for density based measurement using Maglev, the density and magnetic susceptibility of each paramagnetic ionic liquid was first determined (examples shown in FIG. 6). These properties can be calculated from a plot of the levitation height of objects with known density versus their density using previously disclosed methods. See, e.g., Mirica et al. JACS, 2009, 10049. See also, FIGS. 7-9, Table 1.

TABLE 1
(A) Physico-chemical and magnetic properties of the synthesized
paramagnetic ionic liquids (paramagnetic ionic liquids) used for Maglev.
We calculated densities (ρ) and magnetic susceptibilities (χ) using a
previously described method (Mirica et al. JACS, 2009). The aqueous
solubility of each paramagnetic ionic liquid was determined qualitatively
by mixing 5-10 μL of paramagnetic ionic liquids in 1 mL of water.

| paramagnetic | ρ | χ | Solubility | Accessible Density |
|---|---|---|---|---|
| ionic liquid | (g/cm³) | (×10⁻⁴) | (H₂O) | Range (g/cm³) |
| [Aliq]₂ [MnCl₄] | 0.96 | 1.85 | N | 0.90-100 |
| [Aliq]₃ [GdCl₆] | 0.97 | 0.55 | N | 0.95-0.99 |
| [Aliq]₃ [HoCl₆] | 0.95 | 1.94 | N | 0.85-1.05 |
| [Aliq]₃ [HoBr₆] | 1.08 | 1.37 | N | 1.01-1.15 |
| [BMIM]₃ [HoCl₆] | 1.29 | 5.40 | Y | 1.30-1.35 |
| [BMIM] [FeCl₄] | 1.39 | 8.28 | Y | 0.96-1.83 |
| [BMIM]₂ [MnCl₄] | 1.24 | 2.75 | Y | 1.09-1.37 |
| [BMIM]₃ [DyCl₆] | 1.37 | 12.37 | Y | 0.72-2.01 |
| [BDMIM]₃ [DyCl₆] | 1.23 | 3.49 | Y | 1.05-1.41 |
| [AlaC1] [FeCl₄] | 1.52 | 6.62 | Y | 1.15-1.93 |
| [AlaC1]₂ [MnCl₄] | 1.24 | 11.80 | Y | 0.63-1.86 |
| [AlaC1]₃ [GdCl₆] | 1.31 | 8.24 | Y | 0.89-1.74 |
| [AlaC1]₃ [HoCl₆] | 1.42 | 9.70 | Y | 0.92-1.93 |
| [AlaC1]₃ [DyCl₆] | 1.41 | 9.58 | Y | 0.91-1.91 |
| [GlyC2] [FeCl₄] | 1.57 | 5.46 | Y | 1.24-1.81 |
| 4.5M MnCl_{2 (Aq)}* | 1.32 | 4.50 | Y | 1.20-1.55 |

*Not a paramagnetic ionic liquid.

The results demonstrate that each paramagnetic ionic liquid has a unique density and magnetic susceptibility which can be varied by changing the cation or anion (FIGS. 7-9). Variation in the structure of the cation or anion of the paramagnetic ionic liquids can also result in dramatic changes in density and magnetic susceptibility (FIG. 7A). The addition of a methyl group on the imidazolium cation yields a paramagnetic ionic liquid with lower magnetic susceptibility and increased sensitivity (FIG. 7B). In addition, the paramagnetic ionic liquids have different hydrophilic/hydrophobic properties. Accordingly, if a diamagnetic object to be levitated requires a hydrophilic environment, hydrophilic paramagnetic ionic liquids can be utilized. In contrast, if a diamagnetic object to be levitated requires a hydrophobic environment, hydrophobic paramagnetic ionic liquids can be utilized. Some paramagnetic ionic liquids also expand the range of densities that can be measured using MagLev. For instance, [BMIM][DyCl₆] has a magnetic susceptibility (χ=12.4·10⁻⁴); which is about three times greater than that of saturated aqueous MnCl₂ (˜4.5 M, =4.2·10⁻⁴). This paramagnetic ionic liquid, therefore, enables the levitation of analytes across a wider density range than what is accessible to the highest concentration of aqueous MnCl₂ solution (4.5M). Table 1 provides a summary of the physico-chemical properties of all the paramagnetic ionic liquids that was synthesized.

Some of the paramagnetic ionic liquids are viscous making the density standard beads reach their equilibrium levitation height in as long as 60 seconds of being placed with the MagLev device. These viscous paramagnetic ionic liquids can be used for the dynamic separation of objects of different size, but the same density.

### Example 2

### Ionic Liquids for Density Based Authentication of Drugs Using Maglev

Counterfeit medicines pose significant health risks to individual consumers and entire communities, and account for 10% of global pharmaceutical market and up to 50% in some developing countries. Unfortunately, the commonly used instrumentation for counterfeit detection are expensive. For example. Phazir® NIR Material Analyzer, is very expensive, costing at least $25,000. As a consequence, this instrument sees very limited use in the resource limited settings where counterfeiting is most prevalent. A simple, portable, low-cost, and easy-to-use method for identifying counterfeit medications would, therefore, be a valuable tool in the fight against counterfeit drugs.

Paramagnetic ionic liquids can be used for density-based differentiation of some brand name and generic drugs; this demonstration suggests the potential for using paramagnetic ionic liquids for low-cost detection of counterfeit medications using Maglev. The NdFeB magnets cost $5 each (Mirica et al. JACS 2009, 131, 10049-10058). Density measurements of paramagnetic ionic liquid-sized objects using Maglev utilizes about 4 mL of a paramagnetic liquid, this volume of [BMIM][FeCl₄], for example, is estimated to cost <$1.36, and may be recycled many times. For applications such as authentication of drugs, Maglev provides affordable cost of analysis (˜$7 per device) compared to expensive IR based devices such as PHAZIR ($25,000).

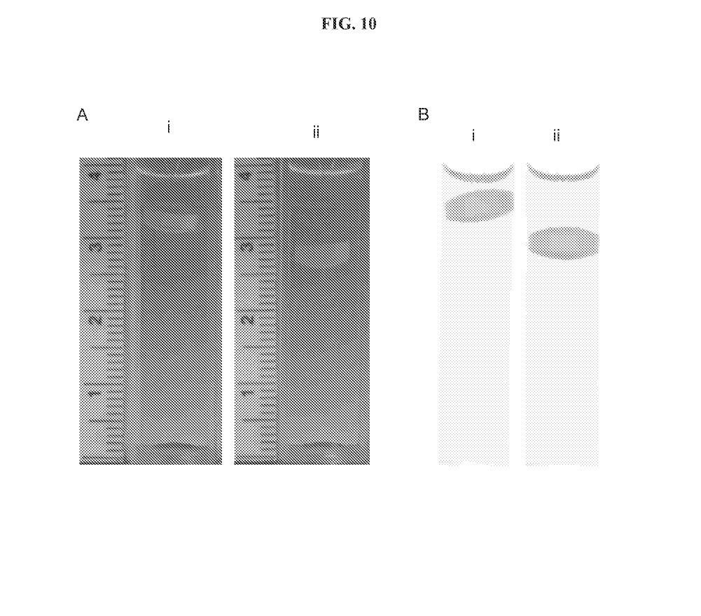

The magnetic susceptibility of the paramagnetic ionic liquids can be decreased by the use of different diamagnetic counterions or by the dilution of a paramagnetic ionic liquid with a diamagnetic ionic liquid and, hence, the sensitivity increased, by diluting the paramagnetic ionic liquids with non-paramagnetic ionic liquids. For instance, [AlaC₁]₃[DyCl₆](diluted with [DMIM][SO₄], 1:1 v/v) and [BMIM][FeCl₄](diluted 1.5× using [DMIM][SO₄]) and were used to distinguish brand name and generic pills of aspirin and naproxen respectively using Maglev (FIG. 10).

### Example 3

### Density Measurements in Sub-Zero Temperatures

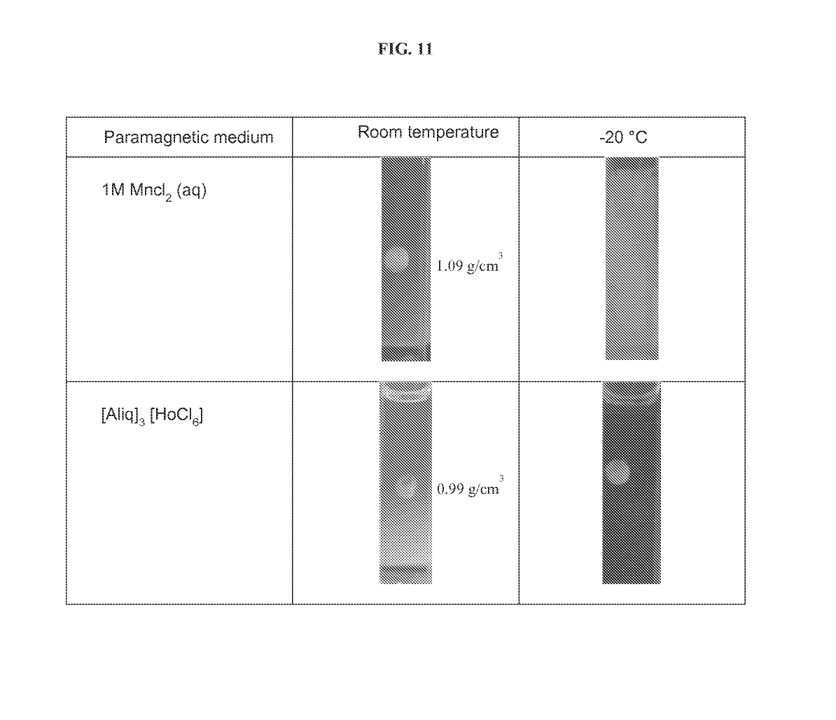

Levitation in aqueous solutions is limited to temperatures above the freezing point of these solutions (˜0° C.). In contrast, paramagnetic ionic liquids can be used over a wide range of temperatures, most having glass transition temperatures well below 0° C. (FIG. 11).

### Example 4

### Dynamic Separations Using Viscous Paramagnetic Ionic Liquids

Viscous paramagnetic ionic liquids, for example [AlaCl]₃[HoCl₆] illustrated here, can be used to dynamically separate objects based on their size. It is often difficult to separate diamagnetic objects based on size in Maglev using paramagnetic salts dissolved in aqueous or organic solvents due to their low viscosity.

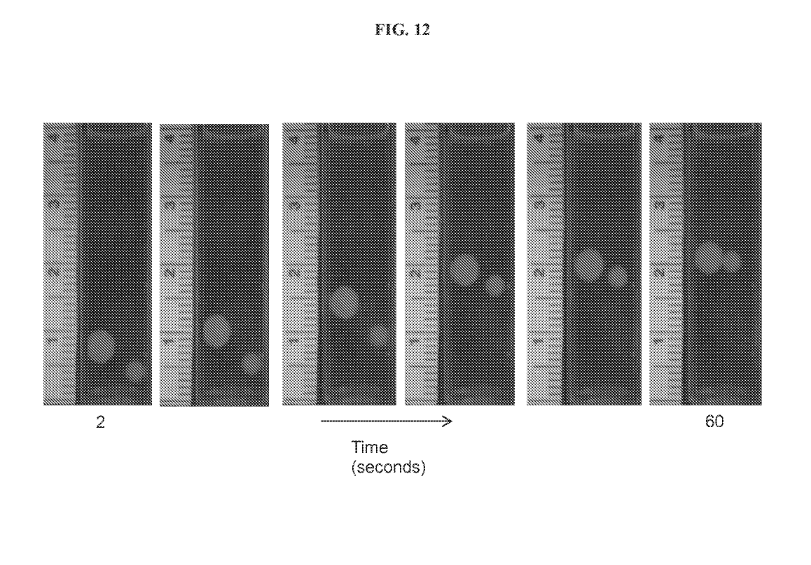

As illustrated herein, the larger Delrin® bead ( 5/32″) always moved faster than the smaller bead (⅛″) during levitation in the viscous paramagnetic ionic liquid, [AlaCl]₃[HoCl₆](FIG. 12).

The invention is described with reference to the following examples, which are provided for the purpose of illustration only and are in no way intended to be limiting of the invention.

Upon review of the description and embodiments of the present invention, those skilled in the art will understand that modifications and equivalent substitutions may be performed in carrying out the invention without departing from the essence of the invention. Thus, the invention is not meant to be limiting by the embodiments described explicitly above, and is limited only by the claims which follow.

What is claimed is:

1. A method for levitating a diamagnetic material comprising:
providing a levitating medium comprising a paramagnetic ionic liquid; and
providing a diamagnetic material in the levitating medium;
applying a magnetic field to the levitating medium and the material; and
determining the levitation height of the material.

2. The method of claim 1, wherein the levitating medium has a vapor pressure that is about zero at room temperature.

3. The method of claim 1, wherein the density of the levitating medium is in the range of 0.65-2.3 g mL⁻¹.

4. The method of claim 1, wherein the levitating medium is free of non-ionic liquid solvent.

5. The method of claim 1, wherein the levitating medium further comprises a diamagnetic ionic liquid.

6. The method of claim 1, wherein the levitation height is correlated to density.

7. The method of claim 1, wherein the levitating medium is a liquid below 0° C.

8. The method of claim 1, wherein the levitating medium is a liquid above 100° C.

9. A method of measuring the density of a liquid or a solid, comprising:
providing a levitating medium comprising a paramagnetic ionic liquid;
introducing a solid or a solvent-immiscible liquid into the levitating medium;
applying a magnetic field having a magnetic gradient to the levitating medium and allowing the solid or liquid to levitate at a position in the levitating medium relative to the magnetic field; and
correlating the levitation height with density.

10. The method of claim 9, wherein the levitating medium is a liquid below 0° C.

11. The method of claim 9, wherein the levitating medium is a liquid above 100° C.

12. The method of claim 9, wherein the levitating medium has a vapor pressure that is about zero at room temperature.

13. The method of claim 9, wherein the density of the levitating medium is in the range of 0.65-2.3 g mL⁻¹.

14. The method of claim 9, wherein the levitating medium is free of non-ionic liquid solvent.

15. The method of claim 9, wherein the levitating medium further comprises a diamagnetic ionic liquid.

16. The method of claim 9, wherein correlating the levitation height with density comprises comparing the levitation height of the unknown solid or solvent-immiscible liquid with a calibration curve to determine the density of the unknown solid or solvent-immiscible liquid.

17. The method of claim 9, wherein the diamagnetic object is a drug and the density determination can distinguish between a known drug product and a counterfeit drug product.
